(19) United States
(12) Patent Application Publication
(10) Pub. No.: US 2023/0402807 A1
(43) Pub. Date: Dec. 14, 2023

(54) FIBER-COUPLED LASER SYSTEMS WITH CONTROLLABLE BEAM SHAPES

(71) Applicant: Panasonic Intellectual Property Management Co., Ltd., Osaka (JP)

(72) Inventors: Takaaki KASSAI, Osaka (JP); Liang CHANG, Boxborough, MA (US); Xinbing LIU, Acton, MA (US); Fangqin LI, Acton, MA (US); Carlton BRULE, Boston, MA (US)

(21) Appl. No.: 17/806,281

(22) Filed: Jun. 10, 2022

(51) Int. Cl. H01S 3/067; H01S 3/08

(52) U.S. Cl. CPC H01S 3/06708; H01S 3/08; G02B 6/02

(57) ABSTRACT

A laser system includes a plurality of laser sources and a plurality of collimating lenses. The system further includes a focus lens configured to receive laser beams outputted from the plurality of collimating lenses and focus the laser beams to at least one focal point in the core region or in the outer cladding region of the optical fiber. The optical fiber includes a core region, an inner cladding region and an outer cladding region, the optical fiber configured to output a dual laser beam comprising a main beam generated from the core region and a ring beam generated from the outer cladding region, the ring beam surrounding the main beam. Each of the plurality of collimating lenses is individually arranged at a respective position so as to adjust a location of the focal point in one of the core region or the outer cladding region of the optical fiber.

### TECHNICAL FIELD

The present disclosure relates to the fiber coupled laser systems with a double-clad fibers. In particular, the fiber coupled laser systems separately couple the laser beams into the core and the cladding regions of the double-clad fiber, and independently control the respective power of each laser beam, and thereby change the output beam shapes dynamically.

### BACKGROUND

High power laser systems are widely used in welding, cutting, drilling and other materials processing, and pump all-solid-state lasers. In these laser processing applications, the desired beam qualities should vary depending on the type of processing or the type of material being processed.

The conventional laser systems need additional processing fiber to change the beam profile, which increases the cost of the system. Also, changing the input beam pointing by mechanical moving optics is relative slow, thus cannot meet the processing requirements, such as quickly changing the beam shapes at a microsecond level.

So, there is a need for improved laser systems capable of changing the laser beam shapes without significantly increasing the cost or additional processing fibers.

### SUMMARY

In one aspect, a laser system for controlling beam profiles, using an optical fiber comprising a core region and an outer cladding region, includes a plurality of laser sources, each laser source configured to generate a corresponding laser beam, and a plurality of collimating lenses, each collimating lens being individually arranged at a respective position to collimate a corresponding laser beam. The system further includes a focus lens configured to receive laser beams outputted from the plurality of collimating lenses and focus the laser beams to form at least one focused beam with a focal point in the core region or the outer cladding region of the optical fiber. The system also includes the optical fiber comprising a core region, an inner cladding region and an outer cladding region, the optical fiber configured to output a dual laser beam comprising a main beam generated from the core region and a ring beam generated from the outer cladding region, the ring beam surrounding the main beam. Each of the plurality of collimating lenses is individually arranged at a respective position to adjust a location of the focal point in the core region or the outer cladding region of the optical fiber.

In one embodiment, a refractive index n_{c} of the core region is greater than a refractive index nₒ of the outer cladding region. Also, the optical fiber further comprises an inner cladding region, wherein the refractive index n_{c} of the core region is greater than a refractive index nᵢ of the inner cladding region, and the refractive index nₒ of the outer cladding region is greater than the refractive index nᵢ of the inner cladding region.

In another embodiment, the plurality of collimating lenses are individually arranged at respective positions by a translation stage including a lens jig to hold a respective collimating lens and a gripper configured to open or close the lens jig.

Also, the plurality of collimating lenses are individually arranged such that a first portion of the laser beams are focused on a first focal point, and a second portion of the laser beams are focused on a second focal point, the first focal point and the second focal point being coaxial or non-coaxial with respect to a propagation direction.

Further, when the first focal point and the second focal point are coaxial, the first focal point is located inside the core region within a threshold depth from an input end of the optical fiber, such that the first portion of the laser beams enter the core region without passing through the outer cladding region, and the second focal point is located inside the core region beyond the threshold depth from the input end of the optical fiber.

In addition, each collimating lens is arranged to move away from or toward a laser source, to adjust a depth of a focal point of a laser beam from an input end of the optical fiber along a propagation direction of the laser beam.

Further, an incidence angle of the first portion of the laser beams is less than a threshold angle θₘₐₓ that is calculated by:

sin θₘₐₓ=\sqrt{n_{c}²−nᵢ²}

Furthermore, the first portion of the laser beams determines the main beam of a beam profile, and the second portion of the laser beams determines the ring beam of the beam profile.

In yet another embodiment, the respective powers of each laser source are individually controlled.

In addition, when a first power for a first laser source emitting the first portion of the laser beams is increased, the main beam has a taller spike, and when a second power for a second laser source emitting the second portion of the laser beams is increased, the ring beam has a taller cylindrical shape.

Further, the laser system further includes a controller configured to adjust a ratio of a summed power for laser sources emitting laser beams coupled to the core region and a summed power for laser sources emitting laser beams coupled to the outer cladding region, to change the beam profile of the dual laser bean.

Additionally, the laser system is configured to output the laser beams with a single wavelength or multiple wavelengths.

In a second aspect, a welding apparatus includes the laser system describe above, and a lens barrel configured to receive the dual laser beam generated from the laser system, and to split, by a mirror, the received dual laser beam into a first dual laser beam for processing a workpiece and a second dual laser beam for monitoring.

In one embodiment, the welding apparatus further includes an image sensor configured to detect a beam profile of the second dual laser beam.

In another embodiment, the welding apparatus further includes a beam profiler indicator configured to indicate an optimum beam profile based on one of a type of the workpieces, a thickness of the workpiece, an amount to be melted, or a scanning speed.

In a third aspect a method for controlling beam profiles using an optical fiber comprising a core region, and an outer cladding region includes generating a plurality of laser beams from a plurality of laser sources, each laser source generating a laser beam, collimating the plurality of laser beams by a plurality of collimating lenses, wherein each collimating lens is individually arranged at a respective position to collimate a corresponding laser beam, directing, by a focus lens, the plurality of laser beams outputted from the plurality of collimating lenses either to the core region or to the outer cladding region optical fiber, and outputting, by the optical fiber, a dual laser beam comprising a main beam generated from the core region and a ring beam generated from the outer cladding region, the ring beam surrounding the main beam, wherein each of the plurality of collimating lenses is individually arranged at a respective position so as to cause a corresponding laser beam to enter one of the core region or the outer cladding region in the optical fiber.

In one embodiment, a refractive index n_{c} of the core region is greater than a refractive index nₒ of the outer cladding region.

In another embodiment, the method further includes arranging each of the plurality of collimating lenses are individually arranged at respective positions by a translation stage including a lens jig to hold a respective collimating lens and a gripper configured to open or close the lens jig.

In yet another embodiment, the method includes adjusting a ratio of a summed power for laser beams coupled to the core region and a summed power for laser beams coupled to the outer cladding region, to control a beam profile of the dual laser beam.

Other aspects, advantages, and salient features of the disclosure will become apparent to those skilled in the art from the following detailed description, which, taken in conjunction with the annexed drawings, discloses exemplary embodiments of the disclosure.

Before undertaking the DETAILED DESCRIPTION below, it may be advantageous to set forth definitions of certain words and phrases used throughout this patent document: the terms “include” and “comprise,” as well as derivatives thereof, mean inclusion without limitation; the term “or,” is inclusive, meaning and/or; the phrases “associated with” and “associated therewith,” as well as derivatives thereof, may mean to include, be included within, interconnect with, contain, be contained within, connect to or with, couple to or with, be communicable with, cooperate with, interleave, juxtapose, be proximate to, be bound to or with, have, have a property of, or the like; and the term “controller” means any device, system or part thereof that controls at least one operation, such a device may be implemented in hardware, firmware or software, or some combination of at least two of the same. It should be noted that the functionality associated with any particular controller may be centralized or distributed, whether locally or remotely. Definitions for certain words and phrases are provided throughout this patent document, those of ordinary skill in the art should understand that in many, if not most instances, such definitions apply to prior, as well as future uses of such defined words and phrases.

### BRIEF DESCRIPTION OF THE DRAWINGS

For a more complete understanding of the present disclosure and its advantages, reference is now made to the following description taken in conjunction with the accompanying drawings, in which like reference numerals represent like parts:

FIGS. 1A to 1C illustrate a fiber coupled laser system with multiple laser sources according to one embodiment of the present disclosure.

FIG. 2 illustrates a magnified view of the input end of the double-clad fiber according to one embodiment of the present disclosure.

FIGS. 3A and 3B illustrate an example of a translation stage for setting each collimating lens at respective positions according to one embodiment of the present disclosure.

FIGS. 4A-4E illustrate various examples of the cross sectional views of the double-clad fiber in which the laser beams propagate, wherein each of the laser beams enters one of either the core region or the outer cladding region of the optical fiber, according to embodiments of the present disclosure.

FIGS. 5A-5E illustrate another various examples of the cross sectional views of the double-clad fiber in which each of the laser beams enters one of either the core region or the outer cladding region of the optical fiber, according to embodiments of the present disclosure.

FIG. 6A illustrates one example of a laser system having a single-wavelength output according to one embodiment of the present disclosure.

FIG. 6B illustrates that the laser system can have a multi-wavelength output according to one embodiment of the present disclosure.

FIG. 7 illustrates a welding device equipped with a laser system capable of controlling beam profiles with a beam profile indicator according to one embodiment of the present disclosure.

FIG. 8 illustrates an example flowchart for controlling beam profiles at a laser system according to one embodiment of the present disclosure.

Throughout the drawings, it should be noted that like reference numbers are used to depict the same or similar elements, features, and structures.

### DETAILED DESCRIPTION

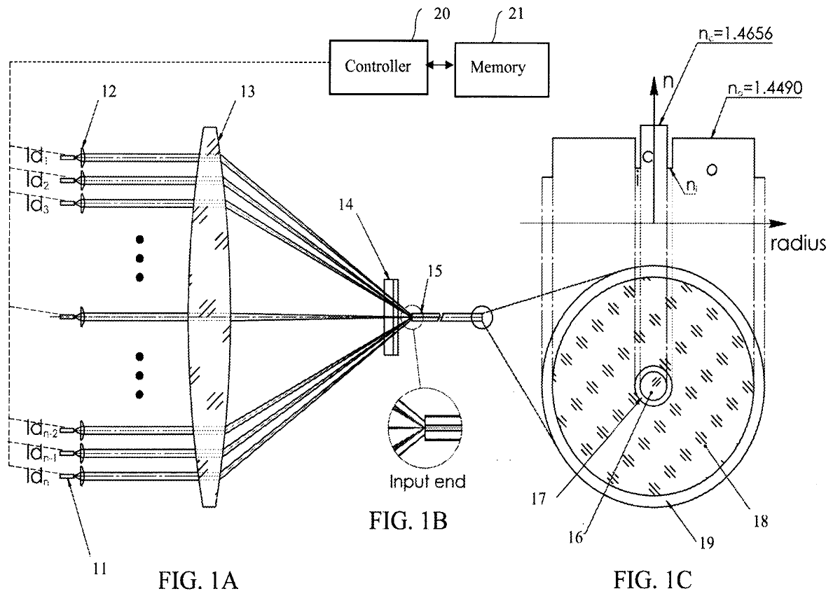

FIGS. 1 through 7, discussed below, and the various embodiments used to describe the principles of the present disclosure in this patent document are by way of illustration only and should not be construed in any way to limit the scope of the disclosure. Those skilled in the art will understand that the principles of the present disclosure may be implemented in any suitably arranged system and method. The following description with reference to the accompanying drawings is provided to assist in a comprehensive understanding of various embodiments of the present disclosure as defined by the claims and their equivalents. It includes various specific details to assist in that understanding but these are to be regarded as mere examples. Accordingly, those of ordinary skill in the art will recognize that various changes and modifications of the various embodiments described herein can be made without departing from the scope and spirit of the present disclosure. In addition, descriptions of well-known functions and constructions may be omitted for clarity and conciseness.

It should be apparent to those skilled in the art that the following description of various embodiments of the present disclosure is provided for illustration purpose only and not for the purpose of limiting the present disclosure as defined by the appended claims and their equivalents.

Although ordinal numbers such as “first,” “second,” and so forth will be used to describe various components, those components are not limited herein. The terms are used only for distinguishing one component from another component. For example, a first component may be referred to as a second component and likewise, a second component may also be referred to as a first component, without departing from the teaching of the inventive concept.

The terminology used herein is for the purpose of describing various embodiments only and is not intended to be limiting. As used herein, the singular forms are intended to include the plural forms as well, unless the context clearly indicates otherwise. It will be further understood that the terms “comprises” and/or “has,” when used in this specification, specify the presence of a stated feature, number, step, operation, component, element, or a combination thereof, but do not preclude the presence or addition of one or more other features, numbers, steps, operations, components, elements, or combinations thereof.

FIG. 1A illustrates an example of a fiber coupled laser system with multiple laser sources according to one embodiment of the present disclosure. FIG. 1B is a magnified view of the input end of the optical fiber. FIG. 1C is a cross section view of the optical double-clad fiber.

Referring to FIG. 1, a fiber coupled laser system 10 comprises a plurality of laser sources 11, a plurality of collimating lenses 12 coupled with translation stages, a focus lens 13, and a cylindrical lens 14, and an optical fiber 15.

Each of the laser sources 11 can be one of gas, liquid and solid state medium that generates a laser beam. Aa an example of a solid state medium, the laser sources are laser diodes (LD). The multiple laser sources 11 can be arranged in one or multiple lines across the focus lens 13.

Laser sources 11 are connected to the controller 20, which individually controls respective powers of the laser sources 11. The controller 20 can include a processor and can be implemented as any combination of hardware, software, or firmware. Also, the controller 20 communicates with a memory 21 to access data used for controlling the respective powers of the laser sources 11 according to the various profiles of the dual laser beams. For example, the memory 21 can store various power levels for each of the laser sources 11 to change the beam profile of the dual laser beam.

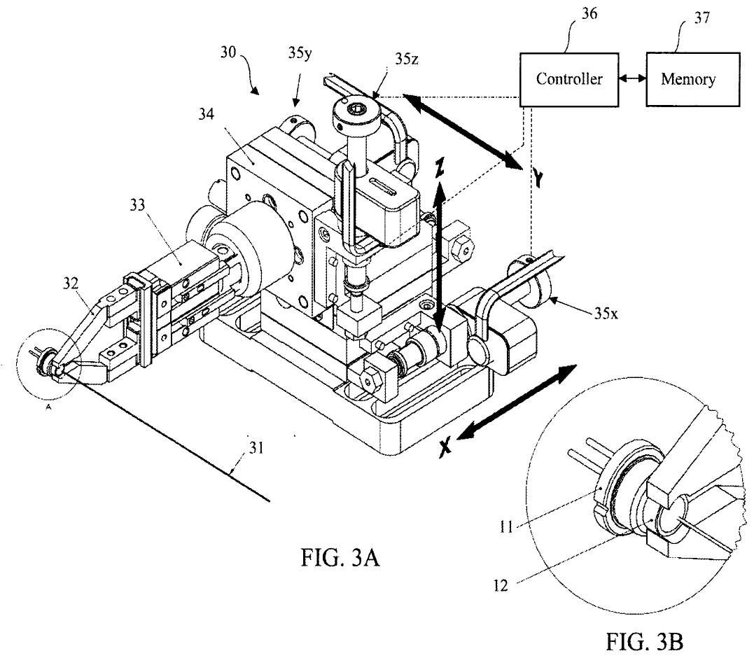

Each of the laser sources 11 is aligned with a individual collimating lens (CL lens), through which a respective laser beam becomes collimated. Each of the collimating lenses 12 are movable in the different perpendicular directions. The detail mechanisms for setting each individual collimating lens are descripted below in reference to FIG. 3A below.

The collimated beams are subsequently received by a focusing system including a focusing lens 13 which focuses the collimated beams on or a focal point located inside the double-clad fiber 15. In one embodiment, the focusing system can additionally include a cylindrical lens 14.

The double-clad fiber 15 includes several regions in different diameters. Specifically, the double-clad fiber 15 includes a core region 16, an inner cladding region 17, an outer cladding region 18, and a jacket 19.

The fiber's core region 16 can be made of glass, plastic, or pure silica. The fiber cladding regions can be made of the same material as the core region, but with a slightly lower index of refraction. For example, the refractive indices of the claddings are usually around 1% lower than that of the fiber core region. For example, with a pure silica fiber core, the inner and outer claddings are made of fluorine-doped silica: however, their fluorine doping concentrations are slightly different, resulting in very small difference between the inner and outer cladding regions.

In the embodiment, the different regions of the double-clad fiber 15 can have respective refractive indices. The refractive index n_{c} of core region 16 is greater than the refractive index nₒ of outer cladding region 18, and both of n_{c} and nₒ are higher than the refractive index nᵢ of inner cladding region 17, thus n_{c}>nₒ>nᵢ.

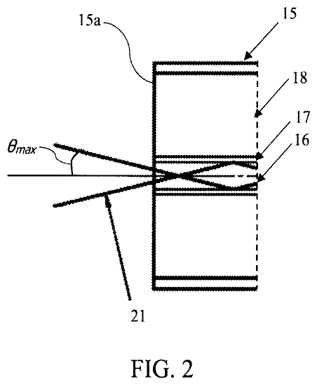

FIG. 2 illustrates a magnified view of the input end of the double-clad fiber according to one embodiment of the present disclosure.

When an incidence angle of the laser beam is equal to or less than (≤) a threshold angle θₘₐₓ, the laser beam 21 will be totally reflected at the boundary between core region 16 and the inner cladding region 17, or between the inner cladding region 17 and outer cladding region 18, and as a result, the laser beam is trapped within core region 16.

The threshold angle θₘₐₓ called a maximum acceptance angle, and the relationship between θₘₐₓ and Numerical Aperture (NA) of optical double-clad fiber is calculated by:

NA=sin θₘₐₓ=\sqrt{n_{c}²−nᵢ²} (1)

FIG. 3A illustrates an example of a translation stage for setting each collimating lens according to one embodiment of the present disclosure. FIG. 3B illustrates a magnified view of the area A in FIG. 3A.

Translation stage 30 is an assembly tool for assembling the laser system. Translation stage 30 is used to arrange each collimating lens 12 at their respective three dimensional positions (x, y, z) such that the laser beams emitted from each diode sources 11 can be coupled to one of the different regions in the optical dual-cladding fiber 15.

The diode laser 11 is mounted on a heatsink (not shown). Each collimating lens 12 is held by a lens jig 32 fixed on a gripper 33. The air gripper 33 closes and holds the lens 12 when compressed air is applied to the gripper 33, conversely, the gripper 33 opens and releases the lens 12 when the pressure is released. The air gripper 33 is mounted on a precision motorized translation stage 30 that enables micro or nano motions in the XYZ directions.

Specifically, translation stage 30 moves the coupled collimating lens 12 away from or toward a laser source 11 in the Y direction, to adjust the entry point of a laser beam on an input end of the optical double-clad fiber. Also, translation stage 30 moves the collimating lens 12 in the X or Z direction to adjust the entry point of a laser beam on an input end of the optical double-clad fiber in a direction perpendicular to the propagation direction of the laser beam within the double-clad fiber 15.

For such XYZ motions, translation stage 30 can include three motors, which are controlled by a computerized controller 36 via a control bus. Specifically, the first and second motors 35x, 35z move the collimating lens in the lateral directions, which are the X and Z directions, and the third motor 35y moves the collimating lens away from or toward the laser source along the Y direction. These motors of translation stage 30 are electrically coupled to the controller 36, which controls the position of collimating lens, based on the desired beam profiles. Also, each of laser sources 11 are individually controlled by controller 36, and respective powers of each laser source 11 are individually controlled by controller 36. The controller 36 can be a processor and can be implemented as any combination of hardware, software, or firmware. Also, controller 36 communicates with memory 37 to access data for controlling translation stage 30.

The translation stage repeats the arrangement processes for each of the collimating lenses 12. Once the arrangement processes for all collimating lenses 12 are complete, the collimating lenses 12 are fixed at the arranged positions, for example, with ultraviolet light (UV) curing glue. After all collimating lenses are glued, the translation stage is removed from the laser system.

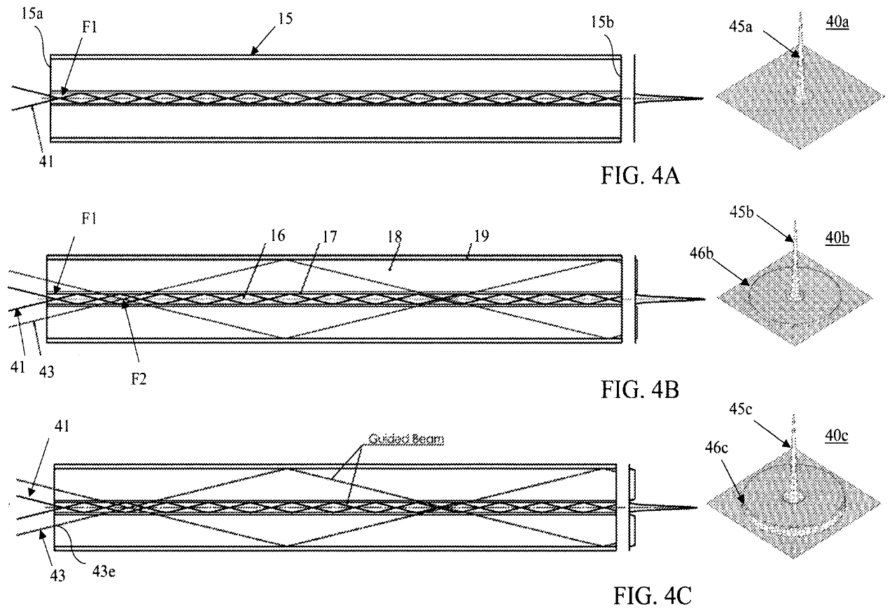

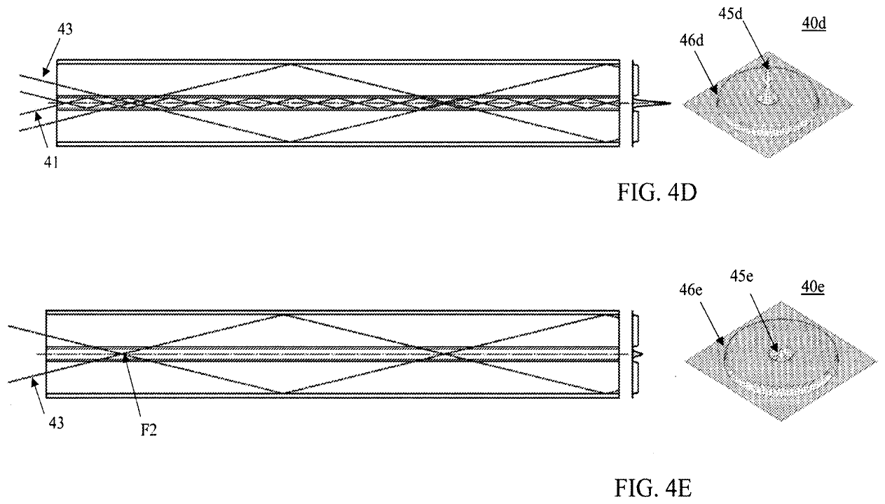

FIGS. 4A-4E illustrate various examples of the cross sectional views of the double-clad fiber in which the laser beams propagate according to embodiments of the present disclosure. In these embodiments, the laser beams have different focal points which are coaxial in the fiber's core along the laser propagation direction.

In these embodiments, the laser beams have different focal points which are coaxial in the fiber's core along the laser propagation direction. These coaxial focal point arrangements can be achieved by changing the positions of each collimating lens. In particular, if the translation stages set a respective collimating lens away from or toward a laser source along the Y axis, a depth of a focal point of a laser beam is adjusted coaxially from an input end of the optical fiber along a propagation direction of the laser beam.

The plurality of collimating lenses are individually arranged at respective positions so that the laser beams can split into multiple focused laser beams after passing through the focus lens. As an example, some of the laser beams form a focused laser beam with a first focal point, and other laser beams form a focused laser beam with a second focal point. The focused laser beam with the first focal point enters the core region and the focused laser beam with the second focal point enters the outer cladding region of the optical dual-cladding fiber.

Also, each laser beam power can be individually controlled by the controller 36, and thereby the power ratio of the main beam and the ring beam at the output end of the fiber can be controlled very flexibly, which results in the controllable dual beam profiles.

In addition, the respective number of laser beams can be controlled by the controller and thereby the power ratio of the main beam and the ring beam at the output end of the fiber can be controlled very flexibly.

FIG. 4A illustrates an example of a cross sectional view of the double-clad fiber in which most of the laser beams are coupled to and guided by the core according to one embodiment of the present disclosure.

As shown in FIG. 4A, all of the laser beams after having passed through focusing system 13 form focused laser beam 41 that enters core region 16 of the optical fiber 15. Focused laser beam 41 has a focal point F1 on or near core region 16 of the input end of the double-clad fiber 15. In this embodiment, the focused laser beam 41 can enter core region 16 without passing through the inner cladding 17 and the outer claddings 18. As a result, most of the focused laser beam 41 is efficiently coupled into core region 16 and are guided by core region 16 of the double-clad fiber 15.

The depth of focal point F1 from the input end 15a is adjusted by setting corresponding collimating lenses away from or toward the laser source along the Y axis.

After being coupled to and trapped within core region 16, the focused laser beam 41 travels through and exits core region 16 at the output end 15b, producing the main beam of the beam profile 40a. In contrast, nₒ laser beams are coupled to outer cladding region 18, which results in the beam profile 40a having nₒ or a negligibly low ring beam.

FIG. 4B illustrates an example of a cross sectional view of the double-clad fiber in which one portion of the laser beams are guided by core region 16 and the other portion of the laser beams are guided by outer cladding region 18 according to one embodiment of the present disclosure.

As shown in FIG. 4B, after having passed through focusing system 13, some of the laser beams form a focused laser beam 41 and the other laser beams form a focused laser beam 43. The focused laser beam 41 enters core region 16 of the optical fiber 15 and has the focal point F1 on or located inside in less than the threshold depth from core region 16 of the input end of the double-clad fiber 15. In the configurations in which the core's refractive index n_{c} is greater than the cladding's refractive index nᵢ, the laser beam coupled to the core region will be trapped into the core to generate the main beam.

Focused laser beam 43 has focal point F2, which is located inside beyond the threshold depth from the input end 15a, such that focused laser beam 43 is coupled into outer cladding region 18. In the configurations in which the refractive index nₒ of the outer cladding is greater than the refractive index nᵢ of the inner cladding, the focused laser beam 43 is trapped within outer cladding region 18 to generate the ring beam.

The depths of focal point F1 and F2 from the input end 15a are adjusted by setting corresponding collimating lenses away from or toward the laser source along the Y axis, as illustrated in FIG. 3A.

The beam profile of an output dual laser beam emitted at the output end 15b is determined by a ratio between a summed power for laser sources emitting the focused laser beam 41 coupled into core region 16 and a summed power for laser sources emitting the focused laser beam 43 coupled into outer cladding 18. Also, the beam diameter of the main beam is determined by the core's diameter, and the beam diameter of the ring beam is determined by a cladding's diameter.

In the embodiment, a greater power is distributed for the focused laser beam 41 and a relatively smaller power is distributed for the focused laser beam 43. Thus, the main beam has a sharp and tall spike and the ring beam has a low cylindrical shape.

FIG. 4C illustrates another example of the cross sectional view of the double-clad fiber in which a portion of the laser beams are guided by core region 16 and another portion of the laser beams are guided by outer cladding 18 according to one embodiment of the present disclosure.

Similar to FIG. 4B, the focused laser beam 41 is coupled to the core to produce the main beam, and the focused laser beam 43 is coupled to outer cladding region 18 and generates the ring beam. One difference is that the power is evenly distributed between the focused laser beam 41 and the focused laser beam 43. Because of the even power distribution, the main beam 45c has a less tall spike, and the ring beam 46c has a taller cylindrical shape, as compared to the beam profile 40b.

FIG. 4D illustrates yet another example of the cross sectional view of the double-clad fiber in which a portion of the laser beams are guided by core region 16 and another portion of the laser beams are guided by outer cladding 18 according to one embodiment of the present disclosure.

Similar to FIGS. 4B and 4C, the focused laser beam 41 is coupled to the core and generates the main beam, and the focused laser beam 43 is coupled into outer cladding region 18 and generates the ring beam. In this embodiment, more power is distributed for the focused laser beam 43 than the focused laser beam 41. Because of this adjusted power distribution, the beam profile 40d has the main beam 45d with a less tall spike, and the ring beam 46d with a taller cylindrical shape, as compared to the beam profiles 40b and 40c.

FIG. 4E illustrates an example of a cross sectional view of the double-clad fiber in which most of the laser beams are coupled to and guided by outer cladding 18 according to one embodiment of the present disclosure.

The focused laser beam 43 travels through and exits outer cladding 18, producing the highest ring beam 46d at the fiber's output end 15b. In contrast, nₒ beams are coupled to the fiber's core region 16, which determines the beam profile 40e having nₒ or a negligibly low main beam.

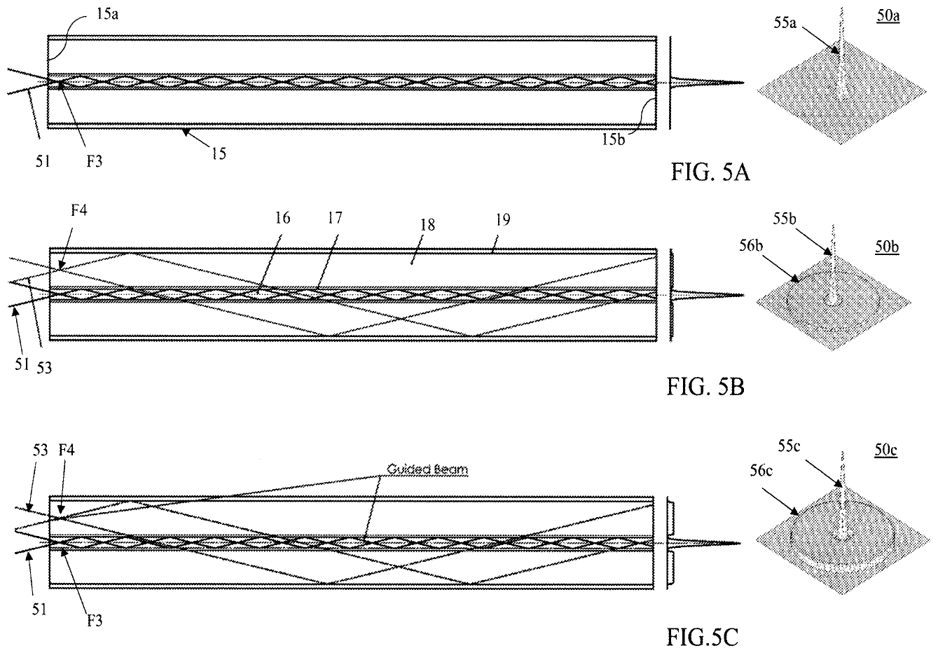

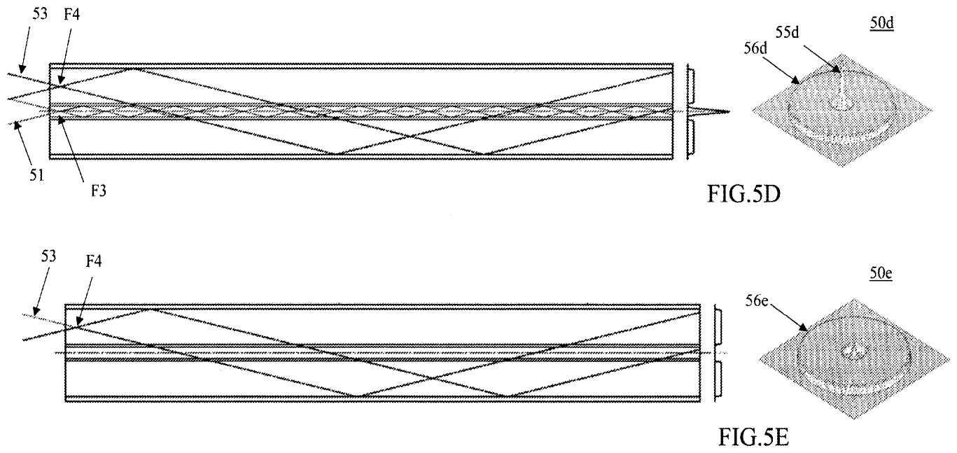

FIGS. 5A-5E illustrate various examples of the cross sectional views of the double-clad fiber in which the laser beams propagate according to embodiments of the present disclosure. In these embodiments, the laser beams have different focal points which are non-coaxial along the laser propagation direction.

The collimating lenses can be individually set at horizontally different positions so that the corresponding focused laser beam enters one of the core region or the outer cladding region at horizontally different entry positions along the X axis, as illustrated in FIG. 3A. Also, the collimating lenses can be individually set at vertically different positions so that the corresponding focused laser beam enters one of the core region or the outer cladding region at vertically different entry positions along the Z axis, as illustrated in FIG. 3A.

Also, the respective powers of each input laser source can be individually controlled by the controller, and thereby the power ratio of the main beam and the ring beam at the output end of the fiber can be controlled very flexibly.

In addition, the respective number of laser beams focused on different focal points can be controlled by the controller, and thereby the power ratio of the main beam and the ring beam at the output end of the fiber can be controlled very flexibly, which enables the controllable dual beam profiles.

FIG. 5A illustrates an example of the cross sectional view of the double-clad fiber in which most of the laser beams are coupled to and guided by core region 16 according to one embodiment of the present disclosure.

Similar to FIG. 4A, focused laser beam 51 with focus point F3 is coupled to and guided by core region 16, and exits fiber 15 at the output end 15b, producing main beam 55a of beam profile 50a. In contrast, nₒ laser beams are coupled to the fiber's cladding 18, which determines beam profile 50a having nₒ or a negligibly low ring beam.

FIG. 5B illustrates an example of the cross sectional view of the double-clad fiber in which one portion of the laser beams are guided by core region 16 and another portion of the laser beams are guided by outer cladding 18 according to one embodiment of the present disclosure.

Similar to FIG. 4B, after having passed through focusing system 13, focused laser beam 51 has focal point F3 on or located inside core region 16 in less than the threshold depth from the fiber's input end 15a. In the embodiment, the refractive index n_{c} of the core is greater than the refractive index nᵢ of the cladding. Because of the reflectivity difference, focused laser beam 51 coupled into core region 16 is trapped within core region 16 to generate main beam 55a.

The other focused laser beam 53 has the focal point F4 located outside core region 16. Since the refractive index nₒ of the outer cladding is greater than the refractive index nᵢ of the inner cladding, focused laser beam 53 is trapped into outer cladding region 18 to generate ring beam 56b surrounding main beam 55b.

The beam profile of an output beam emitted at the fiber's output end 15b is determined by a ratio between the power of the laser sources emitting focused laser beam 51 coupled into core region 16 and the power of the laser sources emitting focused laser beam 53 coupled into outer cladding 18. In the embodiment, more power is distributed for focused laser beam 51 than for focused laser beam 53. As a result, main beam 55b has a sharp and tall spike, and ring beam 56b has a low cylindrical shape.

FIG. 5C illustrates another example of the cross sectional view of the double-clad fiber within which a portion of the laser beams are guided by core region 16 and another portion of the laser beams are guided by outer cladding 18 according to one embodiment of the present disclosure.

Similar to FIG. 5B, focused laser beam 51 is coupled to core region 16 and subsequently produces main beam 55c, and focused laser beam 53 is coupled to outer cladding region 18 and subsequently generates ring beam 54c. One difference is that the power is evenly distributed between focused laser beam 51 and focused laser beam 53. Because of the even power distribution, main beam 55c has a less tall spike, and ring beam 56c has a taller cylindrical shape, as compared to beam profile 50b.

FIG. 5D illustrates yet another example of the cross sectional view of the double-clad fiber within which a portion of the laser beams are guided by core region 16 and another portion of the laser beams are guided by outer cladding 18 according to one embodiment of the present disclosure.

Similar to FIGS. 5B and 5C, focused laser beam 51 is coupled to the core produces the main beam, and focused laser beam 53 is coupled to outer cladding region 18 and generates the ring beam. In contrast, more power is distributed for focused laser beam 53 than for focused laser beam 51. Because of this adjusted power distribution, beam profile 50d has main beam 55d with a less tall spike, and ring beam 56d with a taller cylindrical shape, as compared to beam profiles 50b and 50c.

FIG. 5E illustrates an example of the cross sectional view of the double-clad fiber within which most of the laser beams are coupled to and guided by outer cladding 18 according to one embodiment of the present disclosure.

Focused laser beam 53 travels through and exits outer cladding 18, producing the highest ring beam 55d at the fiber's output end 15b. In contrast, nₒ or only few beams are coupled to the fiber's core region 16, which results in beam profile 50e having nₒ or a negligibly low main beam.

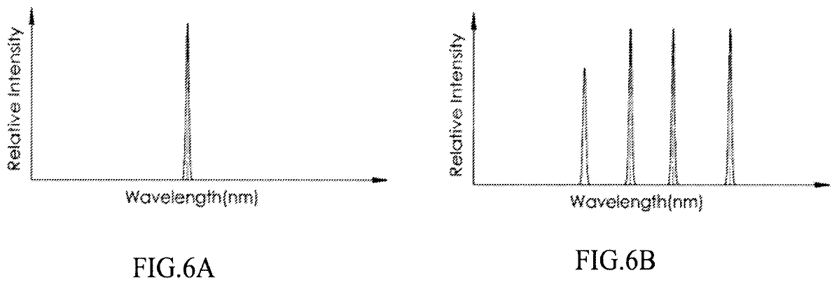

FIG. 6A illustrates one example of a laser system having a single-wavelength output according to one embodiment of the present disclosure. To produce the single-wavelength output, all of the laser sources 11 emit a single wavelength laser beam.

FIG. 6B illustrates that the laser system can have a multi-wavelength output according to one embodiment of the present disclosure. To produce the multi-wavelength output, different laser sources 11 emit laser beams with different wavelengths, which are combined to generate the multi-wavelength output.

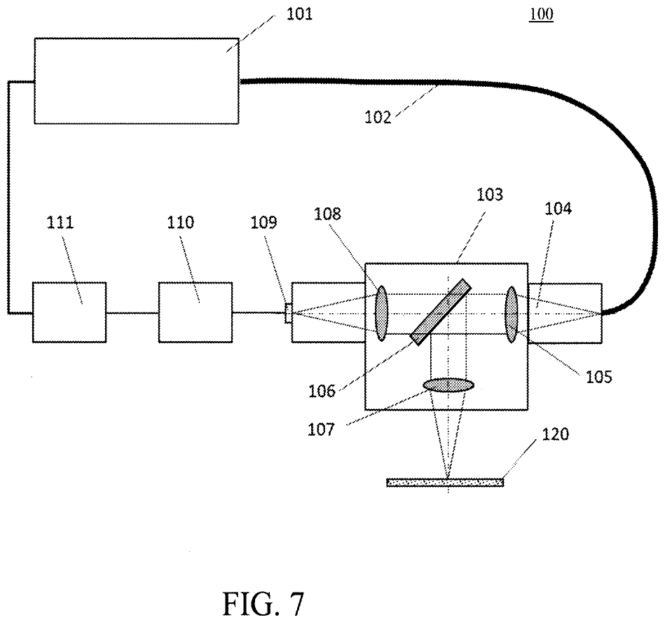

FIG. 7 illustrates a schematic welding device equipped with a laser system configured for controlling beam profiles with a beam profile indicator according to one embodiment of the present disclosure.

The a welding device 100 includes a fiber coupled laser system comprising the laser oscillator 101 and the double-clad fiber 102. The laser oscillator 101 includes laser sources 12, collimating lenses 13 mounted on respective translation stages and a focus lens 14, which are described in detail with reference to FIGS. 1 to 6.

The laser oscillator 101 consists of multiple laser beams and a double-clad fiber, and one portion of the laser beams is couped into and guided by the core region of the double-clad fiber 102 to produce the main beam, the other portion of the laser beams is coupled into and guided by the outer cladding region of the double-clad fiber 102, to generate the ring beam. Each input laser beam can be individually controlled by the controller 20. In particular, the controller 20 adjusts a summed power for the laser sources emitting laser beams coupled to the core region and a summed power for the laser sources emitting laser beams coupled to outer cladding region, which allows for changing the beam profile of the output dual laser beam.

The laser oscillator 101 supplies a plurality of laser beams with different focal points into the double-clad fiber 102, which outputs a dual laser beam including a main beam and a ring beam in different beam profiles.

The dual laser beams are inputted to the lens barrel 103, in which the inputted dual laser beam 104 is collimated by lens 105. The dual laser beam can be split into a dual laser beam for processing materials and a dual laser beam for monitoring by a folded mirror 106 with a 1-2% transmissiveness.

The dual laser beam for processing is condensed by the lens 107 and is irradiated to the workpiece 120.

The dual laser beam for monitoring is condensed by the lens 108 for the beam monitor and is focused on the image sensor 109. The image sensor 109 acquires a beam profile of the dual laser beam which is quantified by the image processing device 110, and the beam profile information is transmitted to a beam profiler indicator 111. The beam profiler indicator 111 can indicate an optimum beam profile based on the processing conditions such as the type of the workpieces and the thickness of the workpiece, the amount to be melted, and the scanning speed.

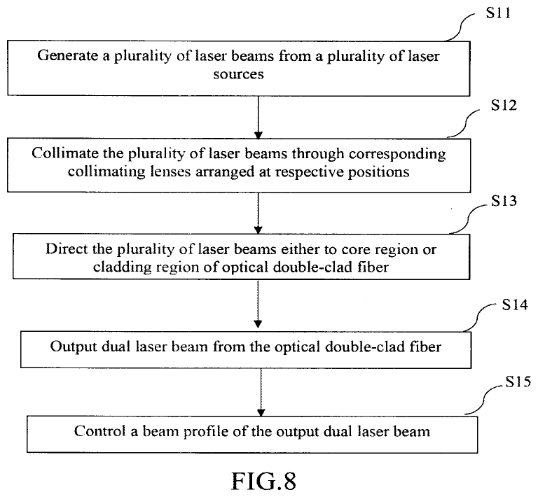

FIG. 8 illustrates a method for controlling beam profiles at a laser system according to one embodiment of the present disclosure.

The method begins with generating a plurality of laser beams from a plurality of laser sources 12, each laser source generating a laser beam in step S11.

In step S12, the plurality of laser beams are collimated by a plurality of collimating lenses 13 coupled with translation stages 30. Each of the plurality of collimating lenses is individually arranged at a respective position so as to cause a corresponding focused laser beam to enter one of the core region or the outer cladding region of the optical fiber 15.

In step S13, the focus lens 13 focuses the plurality of laser beams outputted from the plurality of collimating lenses to form multiple focused beams with different focal points located in different regions of the optical fiber 15.

In step S14, the optical fiber 15 outputs a dual laser beam comprising a main beam generated from the core region and a ring beam generated from the outer cladding region, the ring beam surrounding the main beam.

In step S15, the controller 20 adjusts the respective powers for the laser sources emitting the laser beams coupled to the core region are increased, and the respective powers for the laser sources coupled to the outer cladding region. In other words, the controller 20 adjusts a ratio of the summed power for the laser beams coupled to the core region producing the main beam, and the summed power for the laser beams coupled to the outer cladding region producing the ring beam, thereby changing the beam profile of the output dual laser beam.

The above fiber coupled laser systems and methods replace the single core fiber commonly used in fiber coupled diode laser with a double-clad fiber. Compared with the conventional technologies, the fiber coupled laser system does not need additional optical double-clad fiber and movable mechanical parts to achieve the change of the beam shapes. Also, compared with the conventional technologies, the number of laser sources and types of laser sources are more abundant.

Also, the power of each laser source can be controlled separately, so as to achieve a high-speed (e.g., at a microsecond level) beam shape modulation. Due to a large number of laser sources, the wavelengths of the laser sources are more abundant to meet the processing needs of different materials.

Although the present disclosure has been described with an exemplary embodiment, various changes and modifications may be suggested to one skilled in the art. It is intended that the present disclosure encompass such changes and modifications as fall within the scope of the appended claims.

What is claimed is:

1. A laser system for controlling beam profiles, using an optical fiber comprising a core region and an outer cladding region, comprising:
a plurality of laser sources, each laser source configured to generate a corresponding laser beam;
a plurality of collimating lenses, each collimating lens being individually arranged at a respective position to collimate a corresponding laser beam;
a focus lens configured to receive laser beams outputted from the plurality of collimating lenses and focus the laser beams to form at least one focused beam with a focal point in the core region or the outer cladding region of the optical fiber; and
the optical fiber comprising a core region, an inner cladding region and an outer cladding region, the optical fiber configured to output a dual laser beam comprising a main beam generated from the core region and a ring beam generated from the outer cladding region, the ring beam surrounding the main beam;
wherein each of the plurality of collimating lenses is individually arranged at a respective position to adjust a location of the focal point in the core region or the outer cladding region of the optical fiber.

2. The laser system according to claim 1, wherein:
a refractive index n_{c} of the core region is greater than a refractive index nₒ of the outer cladding region.

3. The laser system according to claim 2, wherein:
the optical fiber further comprises an inner cladding region, wherein
the refractive index n_{c} of the core region is greater than a refractive index nᵢ of the inner cladding region, and the refractive index nₒ of the outer cladding region is greater than the refractive index nᵢ of the inner cladding region.

4. The laser system according to claim 1, wherein:
the plurality of collimating lenses are individually arranged at respective positions by a translation stage including a lens jig to hold a respective collimating lens and a gripper configured to open or close the lens jig.

5. The laser system according to claim 1, wherein:
the plurality of collimating lenses are individually arranged such that a first portion of the laser beams are focused on a first focal point, and a second portion of the laser beams are focused on a second focal point, the first focal point and the second focal point being coaxial or non-coaxial with respect to a propagation direction.

6. The laser system according to claim 5, wherein:
when the first focal point and the second focal point are coaxial,
the first focal point is located inside the core region within a threshold depth from an input end of the optical fiber, such that the first portion of the laser beams enter the core region without passing through the outer cladding region, and
the second focal point is located inside the core region beyond the threshold depth from the input end of the optical fiber.

7. The laser system according to claim 5, wherein:
each collimating lens is arranged to move away from or toward a laser source, to adjust a depth of a focal point of a laser beam from an input end of the optical fiber along a propagation direction of the laser beam.

8. The laser system according to claim 5, wherein:
an incidence angle of the first portion of the laser beams is less than a threshold angle θₘₐₓ that is calculated by:
sin θₘₐₓ=\sqrt{n_{c}²−nᵢ²}

9. The laser system according to claim 1, wherein:
the first portion of the laser beams determines the main beam of a beam profile, and the second portion of the laser beams determines the ring beam of the beam profile.

10. The laser system according to claim 9, wherein:
respective powers of each laser source are individually controlled.

11. The laser system according to claim 10, wherein:
when a first power for a first laser source emitting the first portion of the laser beams is increased, the main beam has a taller spike, and
when a second power for a second laser source emitting the second portion of the laser beams is increased, the ring beam has a taller cylindrical shape.

12. The laser system according to claim 1, further comprising:
a controller configured to adjust a ratio of a summed power for laser sources emitting laser beams coupled to the core region and a summed power for laser sources emitting laser beams coupled to the outer cladding region, to change the beam profile of the dual laser bean.

13. The laser system according to claim 1, wherein:
the laser system is configured to output the laser beams with a single wavelength or multiple wavelengths.

14. A welding apparatus comprising:
the laser system according to claim 1;
a lens barrel configured to receive the dual laser beam generated from the laser system, and to split, by a mirror, the received dual laser beam into a first dual laser beam for processing a workpiece and a second dual laser beam for monitoring.

15. The welding apparatus according to claim 14, further comprising:
an image sensor configured to detect a beam profile of the second dual laser beam.

16. The welding apparatus according to claim 14, further comprising:
a beam profiler indicator configured to indicate an optimum beam profile based on one of a type of the workpieces, a thickness of the workpiece, an amount to be melted, or a scanning speed.

17. A method for controlling beam profiles using an optical fiber comprising a core region, and an outer cladding region, the method comprising:
generating a plurality of laser beams from a plurality of laser sources, each laser source generating a laser beam;
collimating the plurality of laser beams by a plurality of collimating lenses, wherein each collimating lens is individually arranged at a respective position to collimate a corresponding laser beam;
directing, by a focus lens, the plurality of laser beams outputted from the plurality of collimating lenses either to the core region or to the outer cladding region optical fiber; and
outputting, by the optical fiber, a dual laser beam comprising a main beam generated from the core region and a ring beam generated from the outer cladding region, the ring beam surrounding the main beam,
wherein each of the plurality of collimating lenses is individually arranged at a respective position so as to cause a corresponding laser beam to enter one of the core region or the outer cladding region in the optical fiber.

18. The method of claim 17, wherein
a refractive index n_{c} of the core region is greater than a refractive index nₒ of the outer cladding region.

19. The laser system according to claim 2, wherein:
arranging each of the plurality of collimating lenses are individually arranged at respective positions by a translation stage including a lens jig to hold a respective collimating lens and a gripper configured to open or close the lens jig.

20. The method of claim 17, further comprising
adjusting a ratio of a summed power for laser beams coupled to the core region and a summed power for laser beams coupled to the outer cladding region, to control a beam profile of the dual laser beam.
